(19) United States
(12) Patent Application Publication
(10) Pub. No.: US 2024/0036459 A1
(43) Pub. Date: Feb. 1, 2024

(54) PELLICLE FOR EUV LITHOGRAPHY MASKS AND METHODS OF MANUFACTURING THEREOF

(71) Applicant: TAIWAN SEMICONDUCTOR MANUFACTURING COMPANY, LTD., Hsinchu (TW)

(72) Inventors: Wei-Hao LEE, Taipei City (TW); Pei-Cheng HSU, Taipei (TW); Chia-Tung KUO, Hsinchu City (TW); Hsin-Chang LEE, Zhubei City (TW)

(21) Appl. No.: 18/125,464

(22) Filed: Mar. 23, 2023

Related U.S. Application Data
(60) Provisional application No. 63/392,777, filed on Jul. 27, 2022.
(60) Provisional application No. 63/414,256, filed on Oct. 7, 2022.

(51) Int. Cl. G03F 1/62

(52) U.S. Cl. CPC G03F 1/62

(57) ABSTRACT

In a method of manufacturing a pellicle for an extreme ultraviolet (EUV) photomask, a membrane of Sp² carbon is formed, a treatment is performed on the membrane to change a surface property of the membrane, and after the treatment, a cover layer is formed over the membrane.

### RELATED APPLICATIONS

This application claims priority of U.S. Provisional Patent Application No. 63/414,256 filed on Oct. 7, 2022 and U.S. Provisional Patent Application No. 63/392,777 filed on Jul. 27, 2022, the entire contents of each of which are incorporated herein by reference.

### BACKGROUND

A pellicle is a thin transparent film stretched over a frame that is glued over one side of a photo mask to protect the photo mask from damage, dust and/or moisture. In extreme ultraviolet (EUV) lithography, a pellicle having a high transparency in the EUV wavelength region, a high mechanical strength and a low or no contamination is generally required. An EUV transmitting membrane is also used in an EUV lithography apparatus instead of a pellicle.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show pellicles for an EUV photo mask in accordance with embodiments of the present disclosure.

FIGS. 2A, 2B, 2C and 2D show various views of multiwall nanotubes in accordance with embodiments of the present disclosure.

FIGS. 3A, 3B, 3C, 3D and 3E show diagrams of a pellicle in accordance with some embodiments of the present disclosure.

FIGS. 4A, 4B and 4C show a manufacturing process of a network membrane in accordance with an embodiment of the present disclosure.

FIG. 5A shows a manufacturing process of a network membrane, and FIG. 5B shows a flow chart thereof in accordance with an embodiment of the present disclosure.

FIGS. 6A and 6B show a cross sectional view and a plan (top) view of one of the various stages for manufacturing a pellicle for an EUV photo mask in accordance with an embodiment of the present disclosure.

FIGS. 7A and 7B show a cross sectional view and a plan (top) view of one of the various stages for manufacturing a pellicle for an EUV photo mask in accordance with an embodiment of the present disclosure.

FIGS. 8A and 8B show a cross sectional view and a plan (top) view of one of the various stages for manufacturing a pellicle for an EUV photo mask in accordance with an embodiment of the present disclosure.

FIGS. 9A and 9B show a cross sectional view and a plan (top) view of one of the various stages for manufacturing a pellicle for an EUV photo mask in accordance with an embodiment of the present disclosure.

FIG. 10A shows a flow chart and FIGS. 10B and 10C show operations for manufacturing a pellicle for an EUV photo mask in accordance with embodiments of the present disclosure.

FIG. 11 shows a flow chart for manufacturing a pellicle for an EUV photo mask in accordance with embodiments of the present disclosure.

FIGS. 12A and 12B show cross sectional views of the various stages for manufacturing a pellicle for an EUV photo mask in accordance with an embodiment of the present disclosure.

FIGS. 13A and 13B show cross sectional views of the various stages for manufacturing a pellicle for an EUV photo mask in accordance with an embodiment of the present disclosure.

FIGS. 14A and 14B show cross sectional views of the various stages for manufacturing a pellicle for an EUV photo mask in accordance with an embodiment of the present disclosure.

FIGS. 15A and 15B show cross sectional views of the various stages for manufacturing a pellicle for an EUV photo mask in accordance with an embodiment of the present disclosure.

FIG. 16 shows a cross sectional view of one of the various stages for manufacturing a pellicle for an EUV photo mask in accordance with an embodiment of the present disclosure.

FIG. 17A shows a flowchart of a method making a semiconductor device, and FIGS. 17B, 17C, 17D and 17E show a sequential manufacturing operation of a method of making a semiconductor device in accordance with embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore's law. However, due to wavelength scaling from 193 nm (ArF) to 13.5 nm, the EUV light source suffers from strong power decay due to environmental adsorption. Even though the stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In UV or DUV lithography, the pellicle film is made of a transparent resin film. In EUV lithography, however, a resin based film would not be acceptable, and a non-organic material, such as a polysilicon, silicide or metal film, is used.

Carbon nanotubes (CNTs) are one of the materials suitable for a pellicle for an EUV reflective photo mask, because CNTs have a high EUV transmittance of more than 96.5%. Generally, a pellicle for an EUV reflective mask requires the following properties: (1) Long life time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) A good heat dissipation to prevent the pellicle from being burnt out by the EUV radiation. Other nanotubes made of a non-carbon based material are also usable for a pellicle for an EUV photo mask. In some embodiments of the present disclosure, a nanotube is a one dimensional elongated tube having a dimeter in a range from about 0.5 nm to about 100 nm.

In the present disclosure, a pellicle for an EUV photo mask includes a network membrane having a plurality of nanotubes that form a mesh structure. Further, a method of treating the network membrane to remove contaminants and to increase mechanical strength is also disclosed.

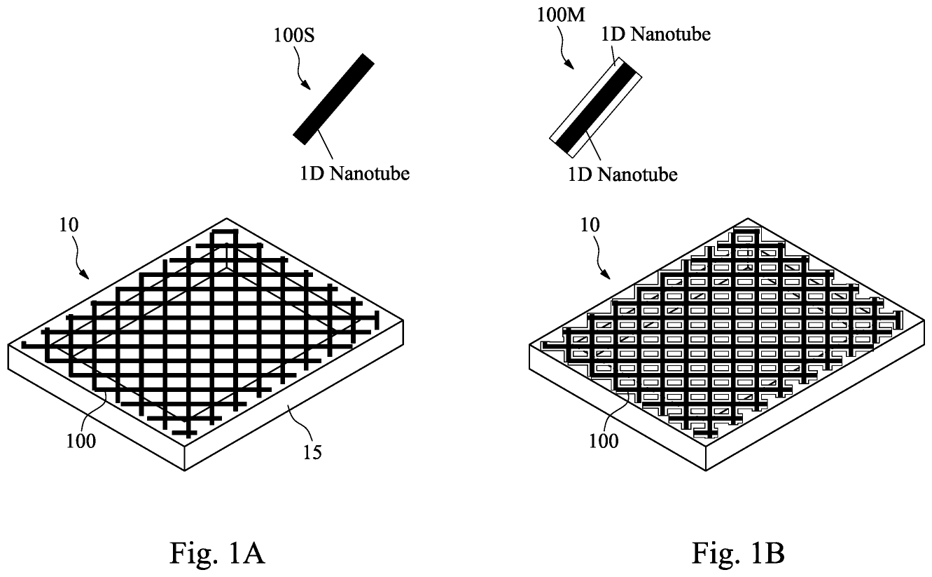

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, as shown in FIG. 1A, the main network membrane 100 includes a plurality of single wall nanotubes 100S, and in other embodiments, as shown in FIG. 1B, the main network membrane 100 includes a plurality of multiwall nanotubes 100D. In some embodiments, the single wall nanotubes are carbon nanotubes, and in other embodiments, the single wall nanotubes are nanotubes made of a non-carbon based material. In some embodiments, the non-carbon based material includes at least one of boron nitride (BN), SiC or transition metal dichalcogenides (TMDs), represented by MX₂, where M=Mo, W, Pd, Pt, and/or Hf, and X═S, Se and/or Te. In some embodiments, a TMD is one of MoS₂, MoSe₂, WS₂ or WSe₂.

In some embodiments, a multiwall nanotube is a co-axial nanotube having two or more tubes co-axially surrounding an inner tube(s). In some embodiments, the main network membrane 100 includes only one type of nanotubes (single wall/multiwall, or material) and in other embodiments, different types of nanotubes form the main network membrane 100.

In some embodiments, a pellicle (support) frame 15 is attached to the main network membrane 100 to maintain a space between the main network membrane of the pellicle and an EUV mask (pattern area) when mounted on the EUV mask. The pellicle frame 15 of the pellicle is attached to the surface of the EUV photo mask with an appropriate bonding material. In some embodiments, the bonding material is an adhesive, such as an acrylic or silicon based glue or an A-B cross link type glue. The size of the frame structure is larger than the area of the black borders of the EUV photo mask so that the pellicle covers not only the circuit pattern area of the photo mask but also the black borders.

In some embodiments, the thickness of the network membrane 100 is in a range from about 5 nm to about 100 nm, and is in a range from about 10 nm to about 50 nm in other embodiments. When the thickness of the network membrane 100 is greater than these ranges, EUV transmittance may be decreased and when the thickness of the network membrane 100 is smaller than these ranges, the mechanical strength may be insufficient.

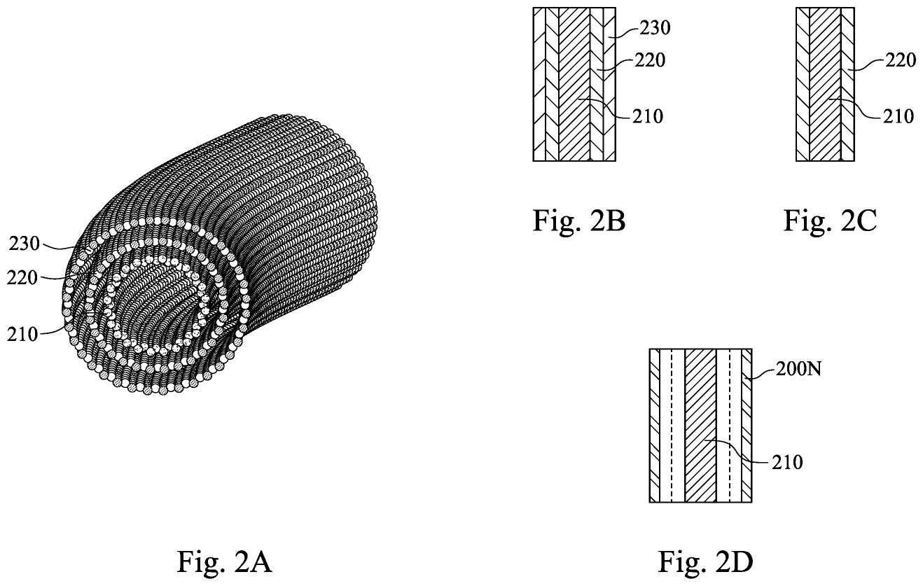

FIGS. 2A, 2B, 2C and 2D show various views of multiwall nanotubes in accordance with embodiments of the present disclosure.

In some embodiments, the nanotubes in the main network membrane 100 include multiwall nanotubes, which are also referred to as co-axial nanotubes. FIG. 2A shows a perspective view of a multiwall co-axial nanotube having threes tubes 210, 220 and 230 and FIG. 2B shows a cross sectional view thereof. In some embodiments, the inner tube 210 is a carbon nanotube, and two outer tubes 220 and 230 are non-carbon based nanotubes, such as boron nitride nanotubes. In some embodiments, all tubes are non-carbon based nanotubes.

The number of tubes of the multiwall nanotubes is not limited to three. In some embodiments, the multiwall nanotube has two co-axial nanotubes as shown in FIG. 2C, and in other embodiments, the multiwall nanotube includes the innermost tube 210 and the first to N-th nanotubes including the outermost tube 200N, where N is a natural number from 1 to about 20, as shown in FIG. 2D. In some embodiments, N is up to 10 or up to 5. In some embodiments, at least one of the first to the N-th outer layers is a nanotube coaxially surrounding the innermost nanotube 210. In some embodiments, two of the innermost nanotubes 210 and the first to the N-th outer layers 220, 230, . . . 200N are made of different materials from each other. In some embodiments, N is at least two (i.e., three or more tubes), and two of the innermost nanotubes 210 and the first to the N-th outer tubes 220, 230, . . . 200N are made of the same materials. In other embodiments, three of the innermost nanotubes 210 and the first to the N-th outer tubes 220, 230, . . . 200N are made of different materials from each other.

In some embodiments, each of the nanotubes of the multiwall nanotube is one selected from the group consisting of a carbon nanotube; a boron nitride nanotube; a transition metal dichalcogenide (TMD) nanotube, where TMD is represented by MX₂, where M is one or more of Mo, W, Pd, Pt, or Hf, and X is one or more of S, Se, or Te. In some embodiments, at least two of the tubes of the multiwall nanotube are made of a different material from each other. In some embodiments, adjacent two layers (tubes) of the multiwall nanotube are made of a different material from each other. In some embodiments, an outermost nanotube of the multiwall nanotube is a non-carbon based nanotube.

In some embodiments, the outermost tube or outermost layer of the multiwall nanotubes is made of at least one layer of an oxide, such as HfO₂, Al₂O₃, ZrO₂, Y₂O₃, or La₂O₃; at least one layer of non-oxide compounds, such as B₄C, YN, Si₃N₄, BN, NbN, RuNb, YF₃, TiN, SiC, or ZrN; or at least one metal layer made of, for example, Ru, Nb, Y, Sc, Ni, Mo, W, Pt, or Bi.

In some embodiments, the multiwall nanotube includes three co-axially layered tubes made of different materials from each other. In other embodiments, the multiwall nanotube includes three co-axially layered tubes, in which the innermost tube (first tube) and the second tube surrounding the innermost tube are made of materials different from each other, and the third tube surrounding the second tube is made of the same material as or different material from the innermost tube or the second tube. In some embodiments, one or more outer tubes are formed around the inner tube, and in other embodiments, one or more tubes are formed in an outer tube.

In some embodiments, the multiwall nanotube includes four co-axially layered tubes each made of different materials A, B or C. In some embodiments, the materials of the four layers are from the innermost (first) tube to the fourth tube, A/B/A/A, A/B/A/B, A/B/A/C, A/B/B/A, A/B/B/B, A/B/B/C, A/B/C/A, A/B/C/B, or A/B/C/C.

In some embodiments, all the tubes of the multiwall nanotube are crystalline nanotubes. In other embodiments, one or more tubes is a non-crystalline (e.g., amorphous) layer wrapping around the one or more inner tubes. In some embodiments, the outermost tube is made of, for example, a layer of HfO₂, Al₂O₃, ZrO₂, Y₂O₃, La₂O₃, B₄C, YN, Si₃N₄, BN, NbN, RuNb, YF₃, TiN, ZrN. Ru, Nb, Y, Sc, Ni, Mo, W, Pt, or Bi.

In some embodiments, a diameter of the innermost nanotube is in a range from about 0.5 nm to about 20 nm and is in a range from about 1 nm to about 10 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 μm to about 50 μm and is in a range from about 1.0 μm to about 20 μm in other embodiments.

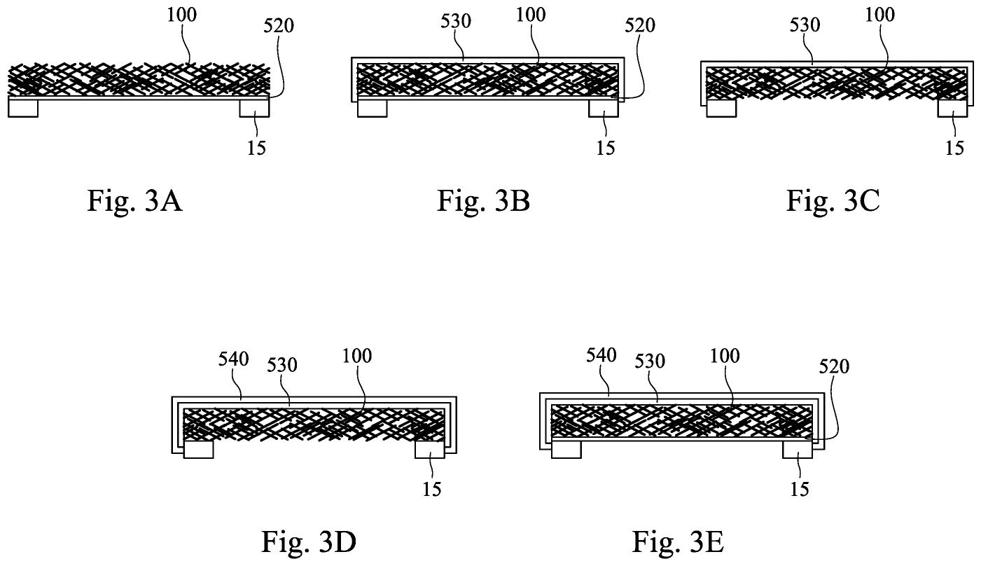

In embodiments of the present disclosure, one or more cover layers or sheets are formed on one or both sides of the membrane 100, as shown in FIGS. 3A-3E. The membrane 100 includes carbon nanotubes and/or 2D material nanotubes as set forth above.

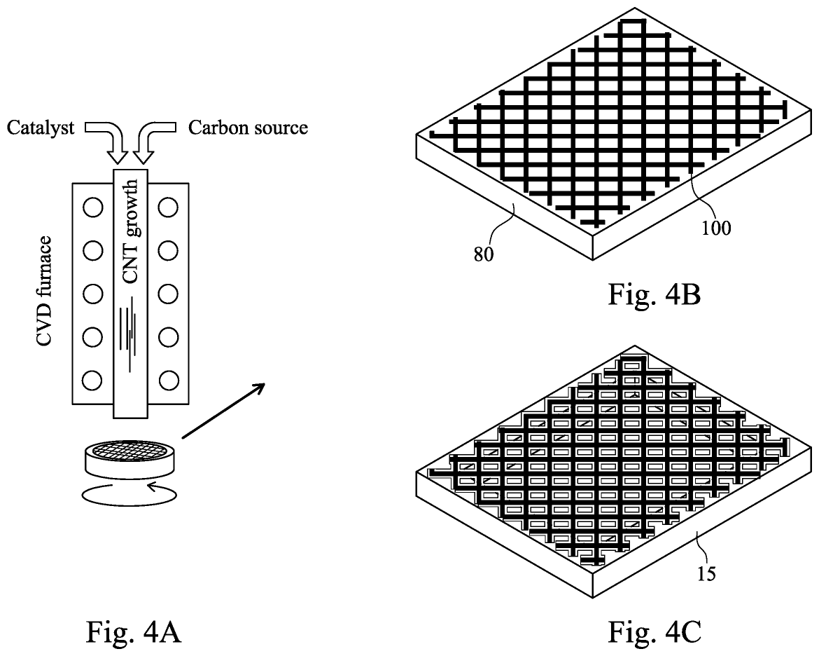

In some embodiments, a first cover layer (or sheet) 520 is formed at the bottom surface of the network membrane 100 between the frame 15 and the network membrane 100 as shown in FIG. 3A. In some embodiments, a second cover layer 530 is formed over the network membrane 100 to seal the network membrane together with the first cover layer 520, as shown in FIG. 3B. In some embodiments, no first cover layer is used and only the second cover layer 530 is used as show in FIG. 3C. In some embodiments, a third cover layer 540 is disposed over the second cover layer 530, as shown in FIG. 4D. In some embodiment, a first cover layer 520, a second cover layer 530 and a third cover layer 540 are formed as shown in FIG. 3E. In some embodiments, the material of the third cover layer 540 is the same as the material of the first and/or second cover layers. In some embodiments, the first, second and third cover layers are made of different material from each other. In some embodiments, a thickness of each of the first cover layer 520 and the second cover layer 530 is in a range from about 0.5 nm to about 10 nm and is in a range from about 1 nm to about 5 nm in other embodiments.

In some embodiments, the first, second and/or third cover layers are formed of carbon, aluminum or an aluminum compound (e.g., AlF₃, Al₂O₃ and AlN), boron or a boron compound (e.g., BN, B₄C, B₂O, and B₆Si), silicon or a silicon compound (e.g., SiN, Si₃N₄, SiN₂, SiC, SiZr, SiC and SiCN), niobium or a niobium compound (e.g., NbSiN, Nb₂O₅, NbTiN, NbSe₃, NbC and Nb₅Si₃), zirconium or a zirconium compound (e.g., ZrN, ZrO₂, ZrYO, ZrF₄, ZrB₂ and ZnSe₂), yttrium or a yttrium compound (e.g., YN, Y₂O₃ and YF₃), molybdenum or a molybdenum compound (e.g., Mo₂N, Mo₅Si₃, Mo₃Si, MoSiB, MoSi, MoC₂, Mo₂B₄, MoC, Mo₂C, MoSe₂, MoS₂, MoN, and MoP), titanium or a titanium compound (e.g., TiN, TiCN and TiS₂), hafnium or a hafnium compound (e.g., HfO₂, HfN and HfF₄), vanadium or a vanadium compound (e.g., VN), tungsten or a tungsten compound (e.g., WS₂ and WSe₂), ruthenium or a ruthenium compound (e.g., RuO₂, RuIrO, Ru₂Ni₂, RuCu, RuPt, RuIr and RuP), iridium or an iridium compound (e.g., IrO₂), cobalt or a cobalt compound (e.g., CoP, CoSe₂ and CoS₂), nickel or a nickel compound (e.g., NiMo), or iron or an iron compound (e.g., Fe₃C, Fe₂O₃ and FePO).

In some embodiments, one of or both of the first cover layer 520 and the second cover layer 530 include a two-dimensional material in which one or more two-dimensional layers are stacked. Here, a “two-dimensional” layer refers to one or a few crystalline layers of an atomic matrix or a network having thickness within the range of about 0.1-5 nm, in some embodiments. In some embodiments, the two-dimensional materials of the first cover layer 520 and the second cover layer 530 are the same or different from each other. In some embodiments, the first cover layer 520 includes a first two-dimensional material and the second cover layer 530 includes a second two-dimensional material.

In some embodiments, the two-dimensional material for the first cover layer 520 and/or the second cover layer 530 includes at least one of boron nitride (BN), graphene, and/or transition metal dichalcogenides (TMDs), represented by MX₂, where M=Mo, W, Pd, Pt, and/or Hf, and X═S, Se and/or Te. In some embodiments, a TMD is one of MoS₂, MoSe₂, WS₂ or WSe₂.

In some embodiments, a number of the two-dimensional layers of each of the two-dimensional materials of the first and/or second cover layers is 1 to about 20, and is 2 to about 10 in other embodiments. When the thickness and/or the number of layers is greater than these ranges, EUV transmittance of the pellicle may be decreased and when the thickness and/or the number of layers is smaller than these ranges, mechanical strength of the pellicle may be insufficient.

In some embodiments, a third cover layer 540 includes at least one layer of an oxide, such as HfO₂, Al₂O₃, ZrO₂, Y₂O₃, or La₂O₃. In some embodiments, the third cover layer 540 includes at least one layer of non-oxide compounds, such as B₄C, YN, Si₃N₄, BN, NbN, RuNb, YF₃, TiN, or ZrN. In some embodiments, the third cover layer 540 includes at least one metal layer made of, for example, Ru, Nb, Y, Sc, Ni, Mo, W, Pt, or Bi. In some embodiments, the third cover layer 540 is a single layer, and in other embodiments, two or more layers of these materials are used as the third cover layer 540. In some embodiments, a thickness of the third cover layer is in a range from about 0.5 nm to about 10 nm, and is in a range from about 1 nm to about 5 nm in other embodiments. When the thickness of the third cover layer 540 is greater than these ranges, EUV transmittance of the pellicle may be decreased and when the thickness of the third cover layer 540 is smaller than these ranges, the mechanical strength of the pellicle may be insufficient.

In some embodiments, one or more of the second or third cover layers also fully or partially cover the side faces of the pellicle frame 15 as shown in FIGS. 3B-3E. In some embodiments, the first cover layer partially or fully covers the side faces of the pellicle frame 15. In some embodiments, one or more of the first, second or third cover layers do not cover the side faces of the pellicle frame.

FIGS. 4A, 4B and 4C show the manufacturing of nanotube network membranes for a pellicle in accordance with embodiments of the present disclosure.

In some embodiments, carbon nanotubes are formed by a chemical vapor deposition (CVD) process. In some embodiments, a CVD process is performed by using a vertical furnace as shown in FIG. 4A, and synthesized nanotubes are deposited on a support membrane 80 as shown in FIG. 4B. In some embodiments, carbon nanotubes are formed from a carbon source gas (precursor) using an appropriate catalyst, such as Fe or Ni. Then, the network membrane 100 formed over the support membrane 80 is detached from the support membrane 80, and transferred on to the pellicle frame 15 as shown in FIG. 4C. In some embodiments, a stage or a susceptor, on which the support membrane 80 is disposed, rotates continuously or intermittently (step-by-step manner) so that the synthesized nanotubes are deposited on the support membrane with different or random directions.

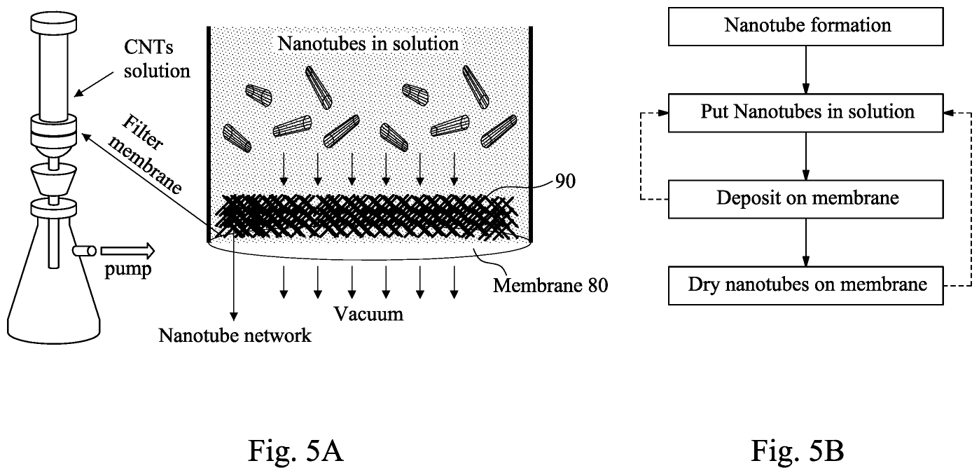

FIG. 5A shows a manufacturing process of a network membrane and FIG. 5B shows a flow chart thereof in accordance with an embodiment of the present disclosure.

In some embodiments, carbon nanotubes are dispersed in a solution as shown in FIG. 5A. The solution includes a solvent, such as water or an organic solvent, and a surfactant, such as sodium dodecyl sulfate (SDS). The nanotubes are one type or two or more types of nanotubes (material and/or wall numbers). In some embodiments, carbon nanotubes are formed by various methods, such as arc-discharge, laser ablation or chemical vapor deposition (CVD) methods.

As shown in FIG. 5A, a support membrane 80 is placed between a chamber or a cylinder in which the nanotube dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm×150 mm square (the size of an EUV mask) can be placed.

As shown in FIG. 5A, the pressure in the vacuum chamber is reduced so that a pressure is applied to the solvent in the chamber or cylinder. Since the mesh or pore size of the support membrane is sufficiently smaller than the size of the nanotubes, the nanotubes are captured by the support membrane while the solvent passes through the support membrane. The support membrane on which the nanotubes are deposited is detached from the filtration apparatus of FIG. 5A and then is dried. In some embodiments, the deposition by filtration is repeated so as to obtain a desired thickness of the nanotube network layer as shown in FIG. 5B. In some embodiments, after the deposition of the nanotubes in the solution, other nanotubes are dispersed in the same or new solution and the filter-deposition is repeated. In other embodiments, after the nanotubes are dried, another filter-deposition is performed. In the repetition, the same type of nanotubes is used in some embodiments, and different types of nanotubes are used in other embodiments. In some embodiments, the nanotubes dispersed in the solution include multiwall nanotubes.

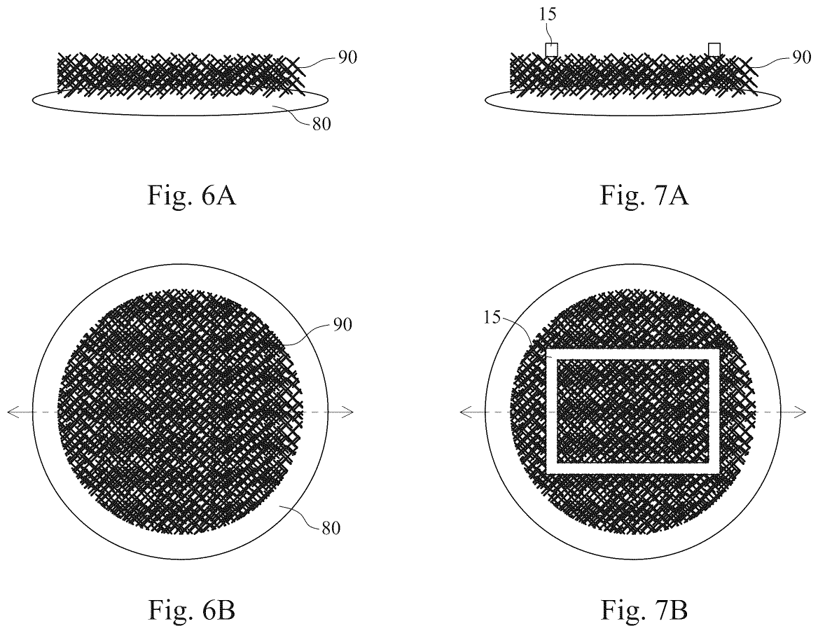

FIGS. 6A and 6B to 9A and 9B show cross sectional views (the “A” figures) and plan (top) views (the “B” figures) of the various stages for manufacturing a pellicle for an EUV photo mask in accordance with an embodiment of the present disclosure. It is understood that additional operations can be provided before, during, and after the processes shown by FIGS. 4A-9B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 6A and 6B, a nanotube layer 90 is formed on a support membrane by one or more method as explained above. In some embodiments, the nanotube layer 90 includes single wall nanotubes, multi wall nanotubes, or mixtures thereof. In some embodiments, the nanotube layer 90 includes single wall nanotubes only. In some embodiments, the nanotubes are carbon nanotubes.

Then, as shown in FIGS. 7A and 7B, a pellicle frame 15 is attached to the nanotube layer 90. In some embodiments, the pellicle frame 15 is formed of one or more layers of crystalline silicon, polysilicon, silicon oxide, silicon nitride, ceramic, metal or organic material. In some embodiments, as shown in FIG. 7B, the pellicle frame 15 has a rectangular (including square) frame shape, which is larger than the black border area of an EUV mask and smaller than the substrate of the EUV mask.

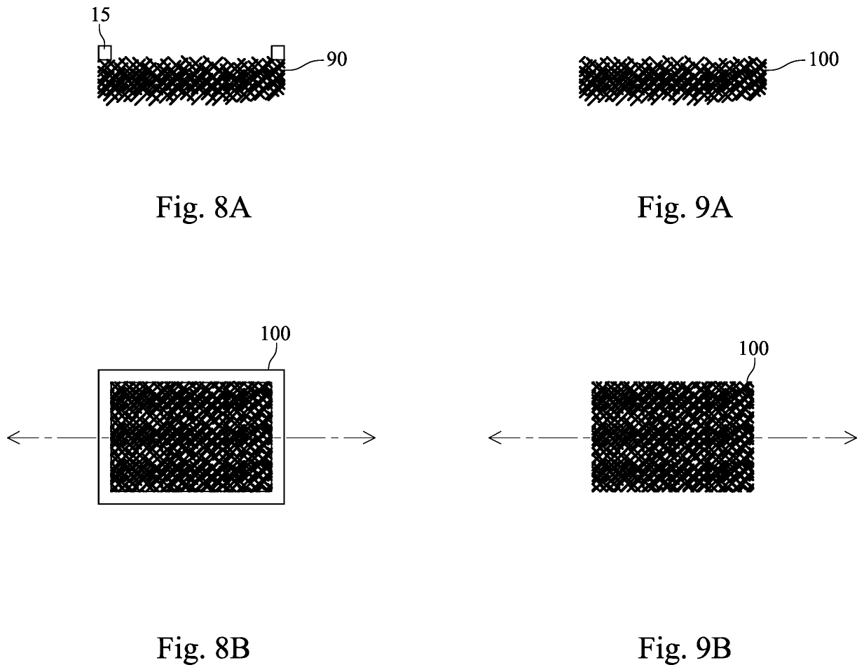

Next, as shown in FIGS. 8A and 8B, the nanotube layer 90 and the support membrane are cut into a rectangular shape having the same size as or slightly larger than the pellicle frame 15, and then the support membrane 80 is detached or removed to form a network membrane 100 in some embodiments. When the support membrane 80 is made of an organic material, the support membrane 80 is removed by wet etching using an organic solvent.

In some embodiments, the nanotube layer 90 is removed from the support membrane before the pellicle frame 15 is attached, as a free standing layer.

As shown in FIGS. 3A-3E, one or more cover layers are formed over the membrane 100 during or after the operations shown in FIGS. 6A-8B. In some embodiments, one or more cover layers are formed over the membrane 100 with the pellicle frame 15 as shown in FIGS. 8A and 8B. In other embodiments, one or more cover layers are formed over the nanotube layer 90 on the support membrane 80 as shown in FIGS. 6A and 6B. In some embodiments, one or more cover layers are formed over the free standing membrane 100 as shown in FIGS. 9A and 9B.

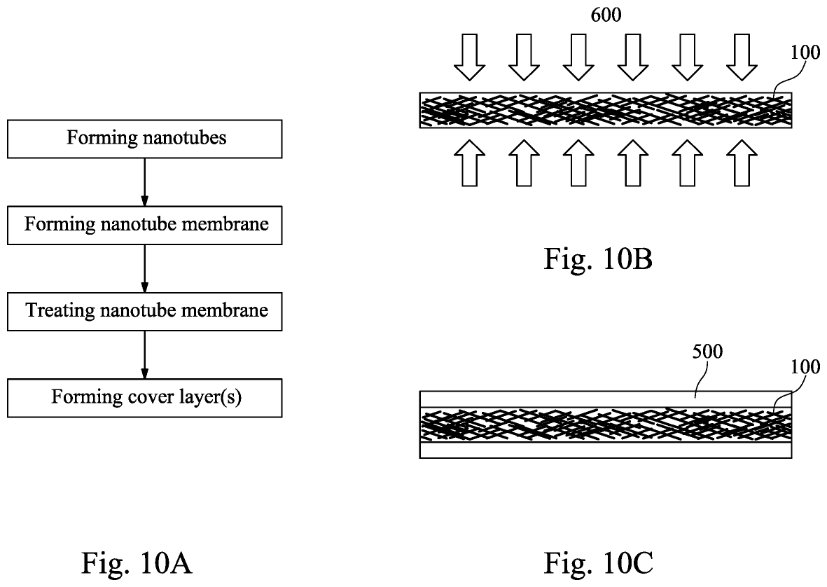

In some embodiments of the present disclosure, before the first and/or second cover layers are formed, the membrane 100 (or nanotube layer 90) is subjected to physical and/or chemical surface treatment 600 to improve adhesiveness of the cover layer and the nanotube membrane, as shown in FIGS. 10A, 10B and 10C. As shown in FIG. 10A, a plurality of nanotubes (e.g., carbon nanotubes) are formed, and a membrane with or without a frame is formed. The nanotube membrane 100 is subjected to physical and/or chemical treatment 600 as shown in FIG. 10B, and thereafter, one or more cover layers 500 consistent with the first, second and/or third cover layers 520, 530, 540 are formed over the nanotube membrane 100 as set forth above, as shown in FIG. 10C.

In some embodiments, the treatment 600 includes chemisorption and/or physisorption to form one or more functional groups on the surface of the nanotube membrane 100. In some embodiments, the functional group includes a hydroxyl group, a sulfhydryl group, a carbonyl group, a carboxyl group, an amino group, and/or a phosphate group.

In some embodiments, the treatment 600 includes applying a solution to the membrane 100 or soaking or immersing the membrane into the solution. The solution includes an organic or inorganic acid solution, a polymer or any organic material having one or more of the functional groups. In some embodiments, the solution includes HNO₃, H₂SO₄, 5-isocyanato-isophthaloyl chloride (ICIC), dodecylamine (DDA), polycaprolactone (PCL), polyacrylic acid (PAA), polydopamine (Pdop), polyaniline (PANI), polymethyl triethyl ammonium chloride (PMTAC), poly(ethylene glycol)methyl ether methacrylate (PEGMA), polysulfobetaine methacrylate (PSBMA), 3-aminopropyl triethoxysilane (APTS), and/or 1,3-phenylenediamine (mPDA).

In some embodiments, the treatment 600 include a gas soaking by applying one or more gases to the membrane. In some embodiments, the membrane and/or the gas are heated at a temperature in a range from about 300° C. to 1200° C. In other embodiments, the temperature is in a range from about 600° C. to 800° C. When the temperature is too high, the membrane may be damaged, and when the temperature is too low, the surface modification may be insufficient. The soaking gas includes one or more of Ar, He, H₂, Ne, N₂ and NH₃, without oxygen. In some embodiments, O₂ is used alternatively or additionally.

In some embodiments, the treatment 600 include a plasma treatment to the membrane. The gas for plasma includes one or more of Ar, He, H₂, Ne, N₂ and NH₃, without oxygen. In some embodiments, O₂ is used alternatively or additionally. In some embodiments, the membrane and/or the gas are heated at a temperature in a range from about 200° C. to 600° C. during the plasma treatment. In other embodiments, the temperature is in a range from about 300° C. to 500° C. The plasma is generated as capacitively coupled plasma, inductively coupled plasma, electron cyclotron plasma, hybrid cold plasma, glow discharge plasma or high pressure arc plasma. The input power of the plasma is in a range from about 1 W to about 2 kW in some embodiments.

After the plasma treatment, the amount of Sp³ carbon structure (disordered or amorphous carbon) increases. In some embodiments, the membrane after the plasma treatment shows a higher peak at the D-band (1360 cm⁻¹) in a Raman spectroscopy and a lower peak at the G-band (1560 cm⁻¹) (corresponding to Sp² carbon structure) than the peaks before the plasma treatment. Since the surface of the nanotube membrane 100 is disordered or caused to have defects or defective sites, adhesion of the cover layer 500 can be improved.

In some embodiments, after the treatment 600 is formed, one or more post treatments are performed. In some embodiments, the post treatment include annealing, such as furnace annealing, rapid thermal annealing, laser annealing, UV annealing, or electron beam annealing.

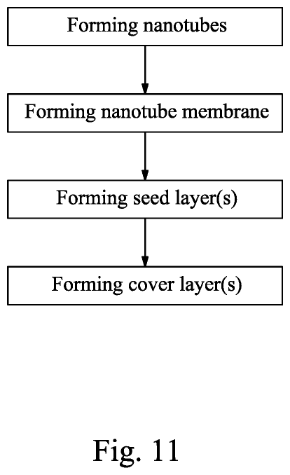

In some embodiments of the present disclosure, one or more seed layers are formed over the surface of the nanotube membrane before the cover layer is formed as show in FIG. 11 and FIGS. 12A-16.

As shown in FIG. 11, a plurality of nanotubes (e.g., carbon nanotubes) are formed, and a membrane with or without a frame is formed. Then, one or more seed layers are formed, and thereafter, one or more cover layers 500 consistent with the first, second and/or third cover layers 520, 530, 540 as set forth above. In some embodiments, the treatment 600 shown in FIG. 10B is performed before the seed layer is formed.

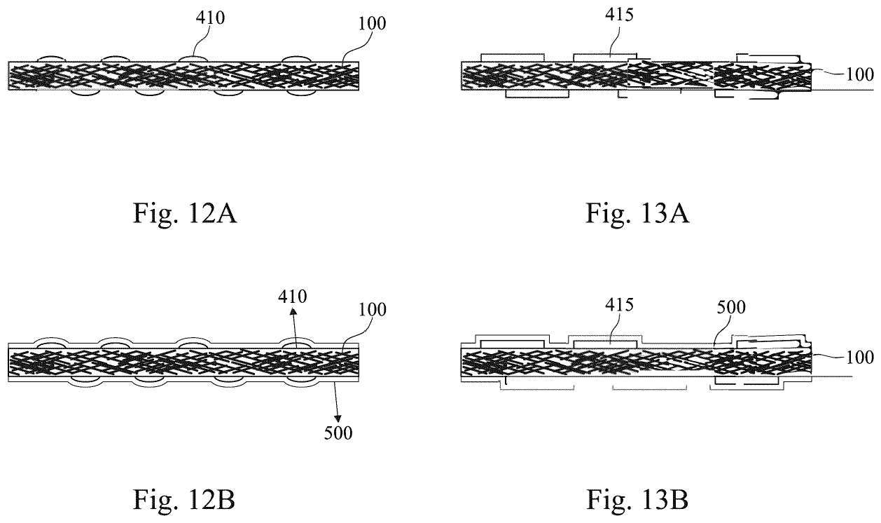

In some embodiments, as shown in FIG. 12A or 13A, a seed layers 410 or 415 are formed over at least one surface of the nanotube membrane 100 not fully covering the surface. In some embodiments, the seed layer includes a plurality of nano-grains or nano-particles 410 having a size in a range from about 5 nm to about 50 nm in plan view. In some embodiments, the seed layer includes a plurality of sheets or islands 415 having a size in a range from about 10 nm to about 1000 nm in plan view. In some embodiments, the thickness of the seed layer is in a range from about 0.5 nm to about 10 nm and is in a range from about 1 nm to about 5 nm in other embodiments.

In some embodiments, the seed layers 410 or 415 cover about 40% to about 60% of the surface area of the nanotube membrane 100. When the coverage is smaller than this range, the cover layer subsequently formed may not fully cover the entire surface of the nanotube membrane. When the coverage is greater than this range, the EUV transmittance of the pellicle may decrease.

After the seed layers 410 or 415 are formed, a cover layer 500 is formed over the nanotube membrane 100 and the seed layer. Since the seed layer only partially covers the surface of the nanotube membrane, the cover layer 500 is in contact with the surface of the nanotube membrane 100.

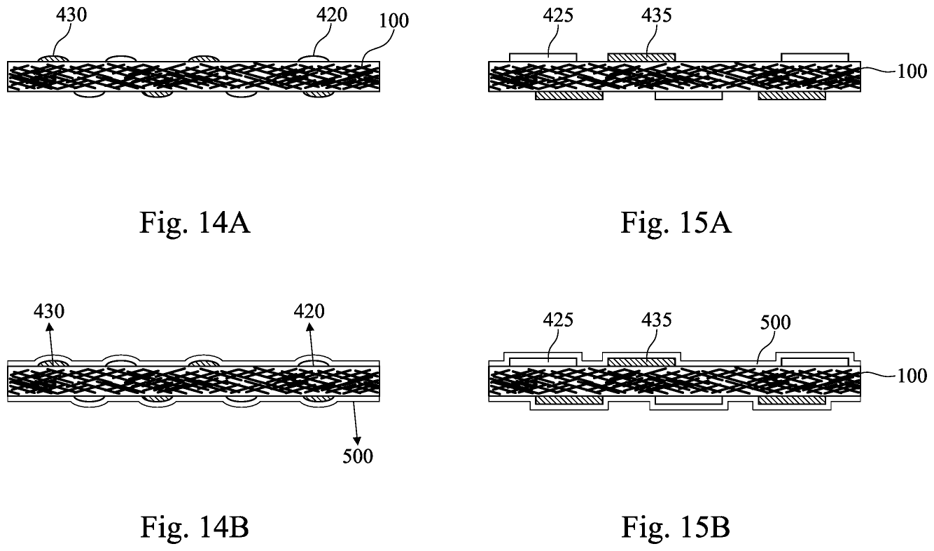

In some embodiments, as shown in FIGS. 14A and 14B, the seed layer includes first nano grains 420 and second nano grains 430 made of different materials from each other, or as shown in FIGS. 15A and 15B, the seed layer includes first sheets or islands 425 and second sheets or islands 435 made of different materials from each other.

In some embodiments, the seed layer includes one or more of C, Al, B, Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Jr, Pt, Au, or Rf, and compounds thereof. The compounds include oxides, nitrides, silicides or carbides.

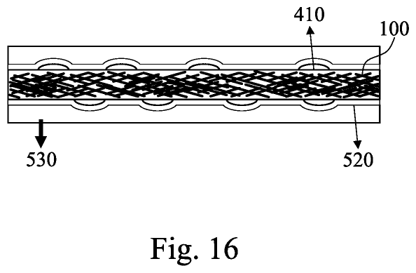

In some embodiments, as shown in FIG. 16, the first cover layer 520 is formed over the seed layer 410 and the nanotube membrane 100 and the second cover layer 530 is formed over the first cover layer 530 and is not in contact with the nanotube membrane 100.

The cover layer and the seed layer can be formed directly over the membrane 100 by at least one of electron beam evaporation (deposition), ion beam deposition, sputtering, chemical vapor deposition (CVD), plasma enhanced CVD, atomic layer deposition (ALD), plasma enhanced ALD, metal-organic CVD (MOCVD), electroplating, or any other suitable film formation methods. In other embodiments, a cover layer formed on a dummy substate is removed and transferred onto the membrane 100.

In some embodiments, after the cover layer is formed, one or more post treatments are performed to re-arrange surface atoms and/or to crystallize the surface or the film. In some embodiments, the post treatment include annealing (e.g., furnace annealing, rapid thermal annealing, laser annealing, UV annealing, or electron beam annealing), or plasma treatment.

In some embodiments, the network membrane includes Sp² carbon structure, such as graphite or graphene in the alternative or in addition to carbon nanotubes.

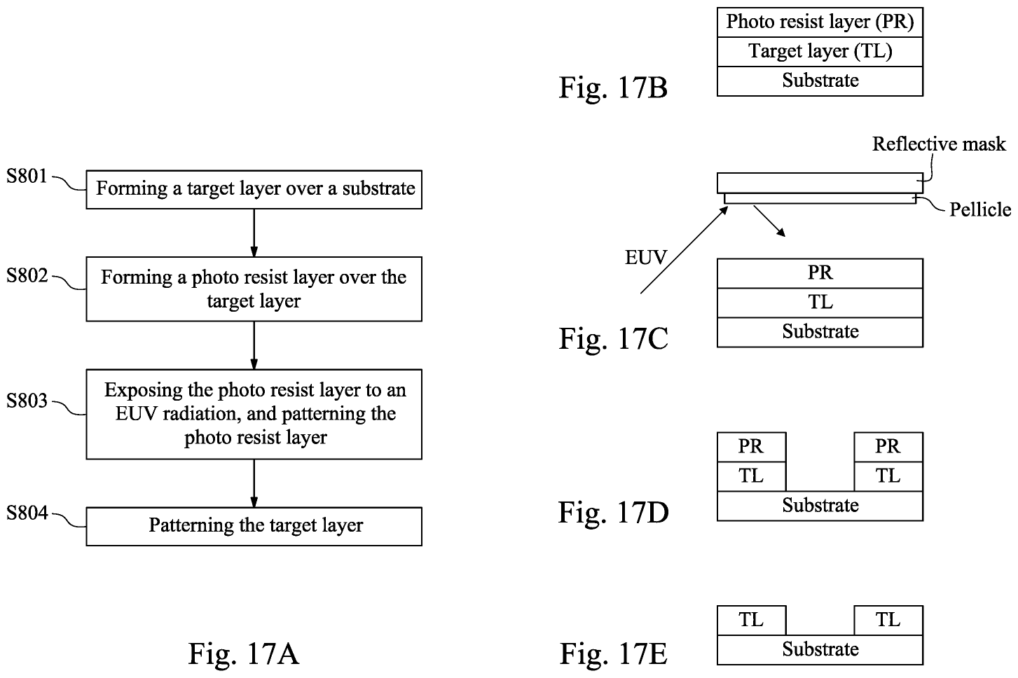

FIG. 17A shows a flowchart of a method of making a semiconductor device, and FIGS. 17B, 17C, 17D and 17E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 17A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802, of FIG. 17A, a photo resist layer is formed over the target layer, as shown in FIG. 17B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer. At S803 of FIG. 17A, the photo resist layer is patterned using an EUV reflective mask with a pellicle as set forth above, as shown in FIG. 17C. The patterning of the photo resist layer includes performing a photolithography exposing process by an EUV exposing system using the EUV mask. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S804 of FIG. 17A, the target layer is patterned utilizing the patterned photo resist layer as an etching mask, as shown in FIG. 17D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma ashing, as shown in FIG. 17E.

In some embodiments, the network membrane including carbon nanotubes as set forth above is used for an EUV transmissive window, a debris catcher disposed between an EUV lithography apparatus and an EUV radiation source, or any other parts in an EUV lithography apparatus and an EUV radiation, where a high EUV transmittance is required.

In the foregoing embodiments, a pellicle membrane includes one or more over layers that reinforce the mechanical strength of the pellicle and improves lifetime of the pellicle.

It will be understood that not all advantages have been necessarily discussed herein, no particular advantage is required for all embodiments or examples, and other embodiments or examples may offer different advantages.

In accordance with one aspect of the present disclosure, in a method of manufacturing a pellicle for an extreme ultraviolet (EUV) photomask, a membrane of Sp² carbon is formed, a treatment is performed on the membrane to change a surface property of the membrane, and after the treatment, a cover layer is formed over the membrane. In one or more of the foregoing and following embodiments, the treatment includes applying at least one solution selected from the group consisting of HNO₃, H₂SO₄, 5-isocyanato-isophthaloyl chloride, dodecylamine, polycaprolactone, polyacrylic acid, polydopamine, polyaniline, polymethyl triethyl ammonium chloride, poly(ethylene glycol)methyl ether methacrylate, polysulfobetaine methacrylate, 3-aminopropyl triethoxysilane, and 1,3-phenylenediamine, to the membrane. In one or more of the foregoing and following embodiments, the treatment includes applying at least one gas selected from the group consisting of Ar, H₂, Ne, O₂, N₂ and NH₃, to the membrane. In one or more of the foregoing and following embodiments, the treatment by gas is performed at a temperature in a range from 300° C. to 1200° C. In one or more of the foregoing and following embodiments, the treatment includes applying plasma to the membrane. In one or more of the foregoing and following embodiments, the treatment causes a surface of the membrane to has at least one selected from the group consisting of a hydroxyl group, a sulfhydryl group, a carbonyl group, a carboxyl group, an amino group and a phosphate group. In one or more of the foregoing and following embodiments, the cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the cover layer includes a single layer or multiple layers of a two-dimensional material. In one or more of the foregoing and following embodiments, the cover layer includes a nano-grain structure, a nano-island structure or a nano-particle structure. In one or more of the foregoing and following embodiments, a thickness of the cover layer is in a range from 0.5 nm to 10 nm. In one or more of the foregoing and following embodiments, the membrane includes at least one of a carbon nanotube, graphene or graphite.

In accordance with another aspect of the present disclosure, in a method of manufacturing a pellicle for an extreme ultraviolet (EUV) photomask, a membrane of Sp² carbon is formed, a seed layer is formed over a principal surface of the membrane, and a cover layer is formed over the membrane and the seed layer. In one or more of the foregoing and following embodiments, the seed layer only partially covers the principal surface of the membrane. In one or more of the foregoing and following embodiments, the seed layer covers 40% to 60% of the principal surface of the membrane. In one or more of the foregoing and following embodiments, the seed layer includes a plurality of openings. In one or more of the foregoing and following embodiments, the seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Jr, Pt, Au and Rf and a compound thereof. In one or more of the foregoing and following embodiments, the seed layer includes two or more different materials. In one or more of the foregoing and following embodiments, the cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO.

In accordance with another aspect of the present disclosure, in a method of manufacturing a pellicle for an extreme ultraviolet (EUV) photomask, a membrane of Sp² carbon is formed, a seed layer is formed over a principal surface of the membrane, a first cover layer is formed over the membrane and the seed layer, and a second cover layer over the first cover layer. In one or more of the foregoing and following embodiments, the seed layer only partially covers the principal surface of the membrane. In one or more of the foregoing and following embodiments, the first cover layer contacts the membrane, and the second cover layer is separated from the membrane by the first cover layer. In one or more of the foregoing and following embodiments, the seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Jr, Pt, Au and Rf and a compound thereof. In one or more of the foregoing and following embodiments, the seed layer includes two or more different materials. In one or more of the foregoing and following embodiments, the first and second cover layers each include at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO.

In accordance with another aspect of the present disclosure, a pellicle for an extreme ultraviolet (EUV) reflective mask includes a membrane including a plurality of nanotubes, and a first cover layer disposed on a first principal surface of the membrane. The first cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the pellicle further includes a seed layer disposed on the first principal surface and only partially covering the first principal surface of the membrane. In one or more of the foregoing and following embodiments, the seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au and Rf and a compound thereof. In one or more of the foregoing and following embodiments, the pellicle further includes a second cover layer disposed on a second principal surface opposite to the first principal surface of the membrane. In one or more of the foregoing and following embodiments, the second cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the first cover layer and the second cover layer are made of a same material. In one or more of the foregoing and following embodiments, the pellicle further includes a third cover layer disposed on a second principal surface opposite to the first principal surface of the membrane. In one or more of the foregoing and following embodiments, the third cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the third cover layer is made of a same material as one of the first cover layer or the second cover layer.

In accordance with another aspect of the present disclosure, a pellicle for an extreme ultraviolet (EUV) reflective mask includes a membrane including a plurality of nanotubes, a first seed layer disposed on a first principal surface of the membrane, and a first cover layer disposed over the first seed layer. The first seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au and Rf and a compound thereof. The first cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the first seed layer only partially covers the first principal surface of the membrane. In one or more of the foregoing and following embodiments, the first seed layer covers 40% to 60% of the principal surface of the membrane. In one or more of the foregoing and following embodiments, the seed layer includes a plurality of openings, and the first cover layer contacts the membrane through the plurality of openings. In one or more of the foregoing and following embodiments, the pellicle further includes a second seed layer disposed on a second principal surface opposite to the first principal surface of the membrane, and a second cover layer disposed over the second seed layer. The second seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au and Rf and a compound thereof. The second cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the first cover layer and the second cover layer are made of a same material. In one or more of the foregoing and following embodiments, the pellicle further includes a third cover layer disposed on the first cover layer. The third cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the third cover layer is made of a same material as one of the first cover layer or the second cover layer. In one or more of the foregoing and following embodiments, the pellicle further includes a second cover layer disposed on the first cover layer. The second cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO. In one or more of the foregoing and following embodiments, the first cover layer and the second cover layer are made of different materials from each other.

In accordance with another aspect of the present disclosure, a pellicle for an extreme ultraviolet (EUV) reflective mask includes a first layer, a second layer, and a main membrane disposed between the first layer and second layer. The main membrane includes a plurality of co-axial nanotubes, each of which includes an inner tube and one or more outer tubes surrounding the inner tube, and two of the inner tube and one or more outer tubes are made of different materials from each other. In one or more of the foregoing and following embodiments, each of the inner tube and the one or more outer tubes is one selected from the group consisting of a carbon nanotube, a boron nitride nanotube, a transition metal dichalcogenide (TMD) nanotube, where TMD is represented by MX₂, where M is one or more of Mo, W, Pd, Pt, or Hf, and X is one or more of S, Se or Te. In one or more of the foregoing and following embodiments, the inner tube is a carbon nanotube. In one or more of the foregoing and following embodiments, each of the plurality of co-axial nanotubes includes the inner tube and one outer tube made of a different material than the inner tube. In one or more of the foregoing and following embodiments, each of the plurality of co-axial nanotubes includes the inner tube and two outer tubes, all of which are made of different materials from each other. In one or more of the foregoing and following embodiments, each of the plurality of co-axial nanotubes includes two outer tubes made of a same material and the inner tube. In one or more of the foregoing and following embodiments, the main membrane further includes a plurality of single wall nanotubes. In one or more of the foregoing and following embodiments, at least one of the first layer or the second layer includes at least one selected from the group consisting of HfO₂, Al₂O₃, ZrO₂, Y₂O₃, La₂O₃, B₄C, YN, Si₃N₄, BN, NbN, RuNb, YF₃, TiN, ZrN, Ru, Nb, Y, Sc, Ni, Mo, W, Pt, and Bi. In one or more of the foregoing and following embodiments, an EUV transmittance of the membrane is 95% to 98%.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a pellicle for an extreme ultraviolet (EUV) photomask, comprising:
forming a membrane of Sp² carbon;
performing a treatment on the membrane to change a surface property of the membrane; and
after the treatment, forming a cover layer over the membrane.

2. The method of claim 1, wherein the treatment includes applying at least one solution selected from the group consisting of HNO₃, H₂SO₄, 5-isocyanato-isophthaloyl chloride, dodecylamine, polycaprolactone, polyacrylic acid, polydopamine, polyaniline, polymethyl triethyl ammonium chloride, poly(ethylene glycol)methyl ether methacrylate, polysulfobetaine methacrylate, 3-aminopropyl triethoxysilane, and 1,3-phenylenediamine, to the membrane.

3. The method of claim 1, wherein the treatment includes applying at least one gas selected from the group consisting of Ar, H₂, Ne, O₂, N₂ and NH₃, to the membrane.

4. The method of claim 3, wherein the treatment by gas is performed at a temperature in a range from 300° C. to 1200° C.

5. The method of claim 1, wherein the treatment includes applying plasma to the membrane.

6. The method of claim 1, wherein the treatment causes a surface of the membrane to have at least one selected from the group consisting of a hydroxyl group, a sulfhydryl group, a carbonyl group, a carboxyl group, an amino group and a phosphate group.

7. The method of claim 1, wherein the cover layer includes at least one layer made of a composition selected from the group consisting of C, Al₂O₃, AN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO.

8. The method of claim 1, wherein the cover layer includes a single layer or multiple layers of a two-dimensional material.

9. The method of claim 1, wherein the cover layer includes a nano-grain structure, a nano-island structure or a nano-particle structure.

10. The method of claim 1, wherein a thickness of the cover layer is in a range from 0.5 nm to 10 nm.

11. The method of claim 1, wherein the membrane includes at least one of a carbon nanotube, graphene or graphite.

12. A method of manufacturing a pellicle for an extreme ultraviolet (EUV) photomask, comprising:
forming a membrane of Sp² carbon;
forming a seed layer over a principal surface of the membrane; and
forming a cover layer over the membrane and the seed layer.

13. The method of claim 12, wherein the seed layer only partially covers the principal surface of the membrane.

14. The method of claim 13, wherein the seed layer covers 40% to 60% of the principal surface of the membrane.

15. The method of claim 12, wherein the seed layer includes a plurality of openings.

16. The method of claim 12, wherein the seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, and Rf and a compound thereof.

17. The method of claim 16, wherein the seed layer includes two or more different materials.

18. The method of claim 12, wherein the cover layer includes at least one layer made of a composition selected from the group consisting of C, Al₂O₃, AlN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrB₂, ZnSe₂, ZrF₄, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO.

19. A pellicle for an extreme ultraviolet (EUV) reflective mask, comprising:
a membrane including a plurality of nanotubes; and
a first cover layer disposed on a first principal surface of the membrane;
wherein the first cover layer includes at least one layer made of a composition selected from the group consisting of C, Al₂O₃, AlN, Al, B, BN, B₄C, B₂O₃, B₆Si, SiN, Si₃N₄, SiN₂, SiC, SiZr, SiC, SiCN, NbSiN, Nb₂O₅, NbTiN, NbSe₃, NbC, Nb₅Si₃, ZrN, ZrO₂, ZrYO, ZrF₄, ZrB₂, ZnSe₂, YN, Y₂O₃, YF₃, Mo₂N, Mo₅Si₃, Mo₃Si, MoSiB, MoSi, MoC₂, Mo₂B₄, MoC, Mo₂C, MoSe₂, MoS₂, MoN, MoP, TiN, TiCN, TiS₂, HfO₂, HfN, HfF₄, VN, WS₂, WSe₂, RuO₂, RuIrO, Ru₂Ni₂, RuCu, RuPt, RuIr, RuP, ZrO₂, IrO₂, CoP, CoSe₂, CoS₂, NiMo, Fe₃C, Fe₂O₃, and FePO.

20. The pellicle of claim 19, further comprising:
a seed layer disposed on the first principal surface and only partially covering the first principal surface of the membrane,
wherein the seed layer is made of one material selected from the group consisting of C, Al, B, Sc, Ti, V, VN, Cr, Mn, Fe, Co, Ni, Cu, Zn, Y, Zr, Nb, Mo, Tc, Ru, Rh, Pd, Ag, Cd, Hf, Ta, W, Re, Os, Jr, Pt, Au and Rf and a compound thereof.
